(19) United States
(12) Patent Application Publication
(10) Pub. No.: US 2026/0170391 A1
(43) Pub. Date: Jun. 18, 2026

(54) ENHANCED MOBILITY SYSTEMS AND ASSOCIATED METHODS FOR SUSPENSION CONTROL AND ROUTE PLANNING

(71) Applicant: AMPHION TECHNOLOGY, LLC, Sterling Heights, MI (US)

(72) Inventors: Eric Patton, Shelby Township, MI (US); Robert Matthews, Sterling Heights, MI (US)

(21) Appl. No.: 18/842,928

(22) PCT Filed: Mar. 28, 2024
(86) PCT No.: PCT/US2024/021842

§ 371 Date: Aug. 30, 2024

Related U.S. Application Data
(60) Provisional application No. 63/456,318, filed on Mar. 31, 2023.
(60) Provisional application No. 63/456,737, filed on Apr. 3, 2023.

(51) Int. Cl. G06N 20/00; G01C 21/34

(52) U.S. Cl. CPC G06N 20/00; G01C 21/343; G01C 21/3461

(57) ABSTRACT

A mobility system for a vehicle may include, among other things, a computing device including one or more processors coupled to memory. The one or more processors may be collectively operable to execute a mobility environment. The mobility environment may be operable to obtain, from a route planner, a proposed route for a vehicle and a mission profile associated with the proposed route. The mobility environment may be operable to assign, using a machine learning model, a route score to the proposed route based on the respective mission profile. The mobility environment may be operable to communicate the route score to the route planner. A method for route planning of a vehicle is also disclosed.

### CROSS-REFERENCE TO RELATED APPLICATION

The present application is a National Phase Entry of International Application No. PCT/US 2024/021842 filed Mar. 28, 2024, which claims the benefit of U.S. Provisional Application No. 63/456318, filed on Mar. 31, 2023, and U.S. Provisional Application No. 63/456737, filed on Apr. 3, 2023, which are incorporated herein in their entireties.

### BACKGROUND

Current robotic platforms have certain limitations in perception that hamper autonomous capability. These limitations are exemplified by issues in determining obstacle density and depth. Examples include differentiating a bush from a boulder and determining puddle depth. Compounding these perception limitations is the extensive processing required to perform route planning and object recognition based on the sensor data capture. The processing load drives size, weight, power and cost (SWAP-C) considerations and generates substantial heat onboard the vehicle, which creates challenges with cooling and signature management.

Existing platforms utilize a series of partial fixes in an attempt to address these problems. Route planning software often takes sub-optimal paths to avoid indeterminant obstacles, or possibly stops all together. Systems have also been driven to investigate active cooling for processors, which adds weight and complexity to the platform.

Existing autonomy systems do not have the capability to resolve the many-to-many relationship created with multiple adaptable vehicle sub-systems, such as semi-active suspension, ride height control systems or differential torques applied through wheel hub motors.

### SUMMARY

A mobility system for a vehicle may include a computing device including one or more processors coupled to memory. The one or more processors may be collectively operable to execute a mobility environment. The mobility environment may be operable to obtain, from a route planner, a proposed route for a vehicle and a mission profile associated with the proposed route. The mobility environment may be operable to assign, using a machine learning model, a route score to the proposed route based on the respective mission profile. The machine learning model may be trained with a training set. The mobility environment may be operable to communicate the route score to the route planner.

In any implementations, the training set may include information associated with traversal of a virtual instance of the vehicle along one or more virtual routes through a simulated terrain with one or more associated mission profiles.

In any implementations, the virtual instance of the vehicle may be associated with a virtual instance of one or more sensors. The training set may include sensor information generated by the virtual instance of one or more sensors.

In any implementations, the training set may include sensor information generated by a physical instance of one or more sensors during traversal of a physical instance of the vehicle along one or more physical routes through a physical terrain with one or more associated mission profiles.

In any implementations, the mobility environment may be operable to cause an adjustment to an adaptive suspension system of the vehicle in response to receiving an approval of the proposed route based on the assigned route score.

In any implementations, the mobility environment may be operable to cause the adjustment prior to traversal of the approved route.

In any implementations, the mission profile may include at least one of a preselected velocity threshold, a preselected noise threshold, and a preselected stability threshold.

In any implementations, the proposed route may include a set of different routes associated with a common origin and/or the same mission profile.

In any implementations, the machine learning model may be operable to assign a safety rating to the proposed route based on a vehicle configuration and the associated mission profile.

In any implementations, the machine learning model may be operable to determine the route score based on the assigned safety rating.

In any implementations, the machine learning model may be operable to determine a health of one or more vehicle components. The machine learning model may be operable to determine the route score based on the determined health.

A mobility system for a vehicle may include a computing device including one or more processors coupled to memory. The one or more processors may be collectively operable to execute a mobility environment. The mobility environment may be operable to obtain sensor information from one or more sensors. The mobility environment may be operable to obtain a proposed route for a vehicle and a mission profile associated with the proposed route. The mobility environment may be operable to evaluate, using a machine learning model, the proposed route with respect to a mission profile. The machine learning model may be trained with a training set. The mobility environment may be operable to cause, prior to traversal of the proposed route, an adjustment to an adaptive suspension system of the vehicle.

In any implementations, the training set may include sensor information generated by a virtual instance of the one or more sensors during traversal of a virtual instance of the vehicle along one or more virtual routes through a simulated terrain with one or more associated mission profiles. The training set may include sensor information generated by a physical instance of the one or more sensors during traversal of a physical instance of the vehicle along one or more physical routes through a physical terrain with one or more associated mission profiles.

In any implementations, the machine learning model is operable to determine a health of one or more vehicle components. The machine learning model may be operable to cause the adjustment to the adaptive suspension system based on the determined health.

In any implementations, the mobility environment may be operable to assign, using the machine learning model, a route score to the proposed route based on the respective mission profile. The mobility environment may be operable to communicate the route score to a route planner for approval of the proposed route.

A method for route planning of a vehicle may include obtaining, from a route planner, a proposed route for a vehicle and a mission profile associated with the proposed route. The method may include assigning, using a machine learning model, a route score to the proposed route based on the respective mission profile. The machine learning model may be trained with a training set. The method may include communicating the route score to the route planner.

In any implementations, the training set may include information associated with traversal of a virtual instance of the vehicle along one or more virtual routes through a simulated terrain with one or more associated mission profiles. The virtual instance of the vehicle may be associated with a virtual instance of one or more sensors. The training set may include sensor information generated by the virtual instance of one or more sensors. The training set may include sensor information generated by a physical instance of the one or more sensors during traversal of a physical instance of the vehicle along one or more physical routes through a physical terrain with one or more associated mission profiles.

In any implementations, the method may include causing, prior to traversal of the proposed route, an adjustment to an adaptive suspension system of the vehicle in response to receiving an approval of the proposed route based on the assigned route score.

In any implementations, the method may include determining, using the machine learning model, a health of one or more suspension components of the vehicle. The method may include causing the adjustment to the adaptive suspension system based on the determined health.

In any implementations, the vehicle may be a tracked vehicle. The one or more suspension components may include a road wheel and/or a track mounted on the road wheel.

The present disclosure may include any one or more of the individual features disclosed above and/or below alone or in any combination thereof.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 discloses a vehicle system including a mobility environment.

FIG. 2 discloses the mobility environment of FIG. 1.

FIGS. 3A-3C disclose implementations of various routes.

FIG. 4 discloses a process for route planning and execution for a vehicle.

Like reference numbers and designations in the various drawings indicate like elements.

### DETAILED DESCRIPTION

Enhanced mobility systems and associated methods for route planning and vehicle component (e.g., suspension) control are disclosed. The disclosed techniques may be utilized to assign or otherwise determine a route score for one or more associated routes. The disclosed systems and methods may be utilized to assign or otherwise determine an expected safety rating relative to the respective route score. The route scores may be established with respect to a mission profile.

The system may be associated with a vehicle including an adaptive (e.g., active) suspension assembly. The system may be operable to pre-activate or otherwise vary one or more suspension parameters associated with the adaptive suspension assembly prior to traversal of the vehicle along the route. The disclosed techniques may be utilized to pre-activate the adaptive suspension assembly based on the route score and/or expected safety rating associated with a selected route.

The disclosed techniques may be incorporated into advanced suspension systems on vehicle development efforts across the U.S. Army, including adaptive damping and ride height control as well as active force inserting suspension systems. Advanced suspension systems may be incorporated into remote-control and manned vehicles.

The system may include or may otherwise interface one or more virtual and/or real sensors. The sensors may be operable to measure or otherwise sense one or more conditions of associated component(s), sub-systems, etc., of the vehicle, such as one or more components of a suspension system.

The disclosed systems and methods may incorporate one or more machine learning models to assign or otherwise determine a route score for one or more routes. The machine learning model(s) may be operable to assign or otherwise determine an expected safety rating associated with the respective route based on various criteria, such as the route score and/or vehicle configuration.

The machine learning model may be trained using training data set(s) for a respective vehicle, vehicle type, route and/or route type. The training set may include any and/or all available suspension settings associated with a suspension system of the vehicle.

The machine learning model may be initially trained using a training set including simulated vehicle dynamics. The training set may be augmented with actual (e.g., real-time) performance data and/or other information associated with operation of the respective vehicle, including the suspension system.

The machine learning model may incorporate a feature importance selection with respect to sensor telemetry data. In implementations, the machine learning model may be operable to ignore sensor data and/or other information that may be relatively less useful for a stated goal which may be associated with a mission profile.

The system may be operable to generate one or more vehicle capability boundaries for each respective vehicle and/or vehicle type.

The machine learning model may be operable to assign or otherwise determine a route score for a respective route based on various parameters associated with the suspension system and/or other portions of the vehicle, such as a speed of the vehicle. The system may include a route planning module that may be operable to determine a suitable speed of the vehicle for traversing the route, which may be based on one or more mission objectives.

The system may include one or more modules operable to provide diagnostics, prognostics, maintenance and/or fault detection functionality, which may be based on collected sensor data and/or other information.

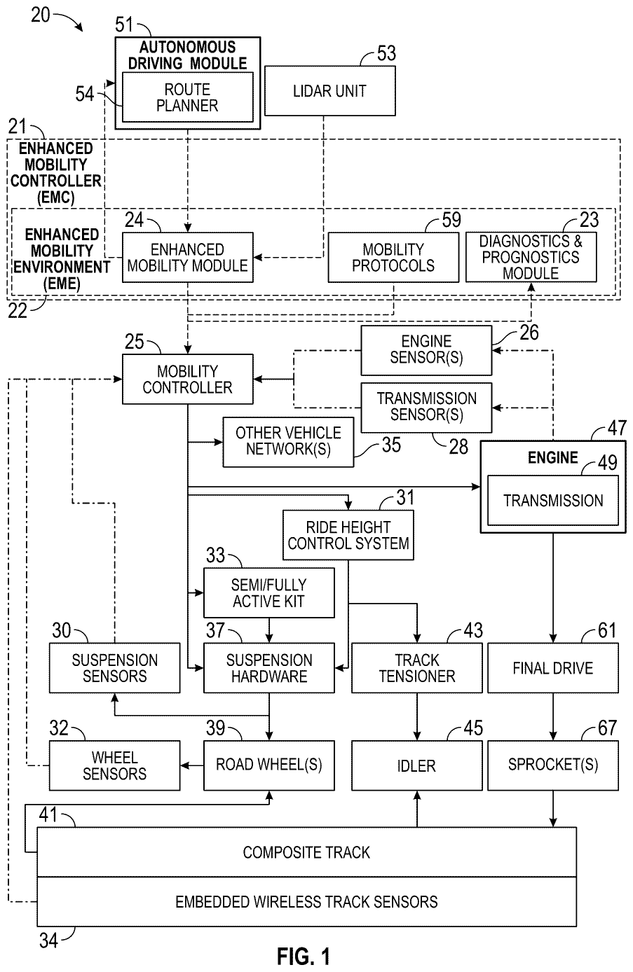

FIG. 1 discloses a system 20 (e.g., vehicle mobility or suspension system) for a vehicle. The system 20 may include an enhanced mobility computing device (e.g., controller) (EMC) 21. The system 20 may include a computing device including one or more processors coupled to memory, such as the EMC 21. The processor(s) may be collectively operable to execute an enhanced mobility environment (EME) 22. In implementations, the EMC 21 may be operable to execute the EME 22. The EME 22 may include one or more modules, or subsystems, such as a diagnostics and prognostics module (DPM) 23 and an enhanced mobility module (EMM) 24. The modules 23, 24 may be operable to communicate with a mobility computing device (e.g., processor or controller) 25.

The DPM 23 may be operable to determine a health of one or more vehicle components 27, including any of the components disclosed herein. The DPM 23 may be operable to assist in route planning based on a determined and/or predicted wear state of the vehicle component(s) utilizing any of the techniques disclosed herein.

The EMM 24 may be a computer-based system operable to determine and/or communicate one or more vehicle capability boundaries to various systems and associated users, including autonomous vehicle route-finding systems, remote operators and/or crewed vehicle drivers. The vehicle capability boundaries may be specified in an associated vehicle configuration 66. The EMM 24 may include a capability model of high-fidelity mobility simulation. The capability model may be operable to generate relatively high-fidelity mobility simulation results. The EMM 24 may be operable to reference results of the simulation against real-world and real-time sensor data to provide an (e.g., expected) safety rating relative to a route scoring determination. The EMM 24 may be operable to pre-activate one or more adaptive suspension parameters in a predictive way, as opposed to a reactive way. The EMM 24 may be operable to reference the mobility simulation results against real sensor data to provide an expected safety rating and/or estimate or otherwise provide (e.g., optimal) suspension system setting(s) for controlling (e.g., varying) operation of an adaptive suspension system, including a ride height control system 31. The methods and systems disclosed herein may improve operating performance and may reduce and distribute processor burden to assist in cooling challenges.

The mobility controller 25 may be operable to communicate with one or more mobility subsystems, including any of the subsystems disclosed herein, such as the ride height control system 31, semi-and/or fully-active kit (e.g., damping system) 33, and/or other vehicle networks 35.

The damping system 33 may be a semi-active or fully-active damping system. Semi-active damping systems allow the ride quality to be optimized via damping changes to match the requirements of different operational scenarios or to minimize energy dissipation and associated fuel consumption when high levels of damping are not of immediate benefit. Semi-active damping currently use analysis of vehicle motion to actively control the damping force generated as a result of a given input velocity. Hydro-pneumatic suspension systems incorporating the adaptive damping principle present a significant step forward in the mobility of both tracked and wheeled military vehicles.

The ride height control system 31 may be operable to control operation of various components of the vehicle, such as suspension hardware 37, road wheel(s) 39, (e.g., composite) track(s) 41, track tensioner(s) 43 and/or idler(s) 45. The track 41 may be mounted on the road wheel(s) 39. The ride height control system 31 may be operable to change ground clearance of the vehicle, as well as posture and attitude relative to the ground. The ride height control system 31 may facilitate increased operational modes allowing for passing obstacles that might otherwise hinder vehicle operation. The ride height control system 31 and/or (e.g., semi-active) damping system 33 may increase the operational profile of the vehicle. The techniques disclosed herein may include incorporating the height control system 31 and/or (e.g., semi-active) damping system 33 into route planning and execution for the associated vehicle.

The mobility controller 25 may be operable to receive sensor data from one or more sensors associated with various components of a vehicle, including any of the sensors disclosed herein. The sensors may be distributed at different positions relative to each other, including different positions within and/or on the vehicle such that the sensors may be spaced apart from each other and/or a centroid of the vehicle. In implementations, the EMC 21 and/or EME 22 may be incorporated into the mobility controller 25, or vice versa. Various vehicles may benefit from the teachings disclosed herein, including on-road and/or off-road vehicles such as wheeled and/or tracked vehicles.

The EMC 21 and/or mobility controller 25 may include one or more computer processors, memory, storage means, network devices, input and/or output devices, and/or interfaces. The EMC 21 and/or mobility controller 25 may be operable to execute one or more software programs. The EMC 21 and/or mobility controller 25 may be operable to communicate with one or more networks established by one or more computing devices. The memory may include UVPROM, EEPROM, FLASH, RAM, ROM, DVD, CD, a hard drive, or other computer readable medium which may store data and/or the functionality of this description. The EMC 21 and/or mobility controller 25 may be a desktop computer, laptop computer, smart phone, tablet, or any other computer device. Input devices may include a keyboard, mouse, touchscreen, etc. The output devices may include a monitor, speakers, printers, etc. The EMC 21 and/or mobility controller 25 may include one or more processors coupled to memory. The connection may be a wired and/or wireless connection. The connection may be established over one or more networks and/or other computing systems. The EMC 21 and/or mobility controller 25 may be programmed with logic to perform any of the functionality disclosed herein. In implementations, processing of the various data and other information disclosed herein may be performed by the EMC 21 and/or mobility controller 25 either onboard and/or offboard the vehicle.

The mobility controller 25 may be operable to receive (e.g., wired) sensor data (illustrated as dash-dot lines) from corresponding engine sensor(s) 26, transmission sensor(s) 28, vehicle suspension sensors 30, and/or vehicle wheel sensors 32, and/or (e.g., wireless) sensor data (illustrated as dash-double-dot lines) from embedded track sensors 34 associated with the (e.g., composite) track 41 of a tracked vehicle.

Different types of sensors may provide corresponding sensor data from various components and sub-systems of the vehicle, including any of the sensors, components and sub-systems disclosed herein. With respect to vehicular suspension hardware (e.g., system) 37, rotary position sensor(s) may be operable to collect and/or communicate real-time rotary position sensor data. Linear position sensor(s) may be operable to collect and/or communicate linear position sensor data. The sensors may include one or more inertial motion sensors (e.g., Inertial Motion Unit, “IMU”), such as an accelerometer, gyroscope, etc. The inertial motion sensor(s) may be operable to collect and/or communicate 3-axis inertial sensor data. Pressure sensor(s) may be operable to collect and/or communicate internal pressure (e.g., hydraulic) sensor data. Stress and/or strain gauge sensor(s) may be operable to collect and/or communicate stress and/or strain gauge sensor data with respect to various suspension components (e.g., hardware) 37 of a vehicle, the vehicle hull, wheel(s) 39 and/or track(s) 41 of a tracked vehicle.

With respect to engine and transmission sensors 26, 28, engine sensors 26 may be operable to collect and/or communicate real-time RPM, load and throttle position data. Transmission sensors 28 may be operable to collect real-time input RPM, output RPM, direction and/or gear selection data of the vehicle. Both an engine 47 and transmission 49 may be operable to receive brake commands associated with the respective (e.g., tracked) vehicle(s). A final drive 61 and sprocket 67 may be associated with the engine 47 and transmission 49 and/or the track 41.

With respect to vehicle dynamic performance characteristics, one or more steering sensors may be operable to collect realtime vehicular steering data. One or more braking sensors may be operable to collect realtime braking data. One or more acceleration sensors may be operable to collect realtime acceleration data.

Additional sensors that may be characterized as non-specific to a vehicle platform may be operable to collect and/or communicate data related to a geographic location and atmospheric conditions to better predict wear rates and failure modes based on geographic locations (e.g., abrasive sand parameters of a particular arid location, or corrosive sea water-based humidity in coastal tropical locations). The sensors may be onboard the vehicle or may be remotely located from the vehicle and may be operable to communicate data utilizing any of the techniques disclosed herein.

Geo-location sensor(s) (e.g., Global Positions System (GPS) receivers), temperature sensor(s), humidity sensor(s) and/or barometric pressure sensor(s) may be operable to provide this data, which may be utilized to better predict wear rates and failure modes particularly when vehicle(s) may be operated in diverse geographies and climates over their operational service life.

The mobility controller 25 may be operable to communicate the collected sensor signal data to the EMC 21.

The autonomous driving module 51 may include a route planner 54. The route planner 54 may be operable to determine one or more proposed and/or approved routes for the vehicle along the terrain.

The EMM 24 and/or another portion of the EME 22 may be operable to communicate with the autonomous driving module 51 and/or a navigational subsystem such as a light detection and ranging (LIDAR) unit 53.

The various subsystems and components may communicate or otherwise interface via one or more predefined mobility protocols 59.

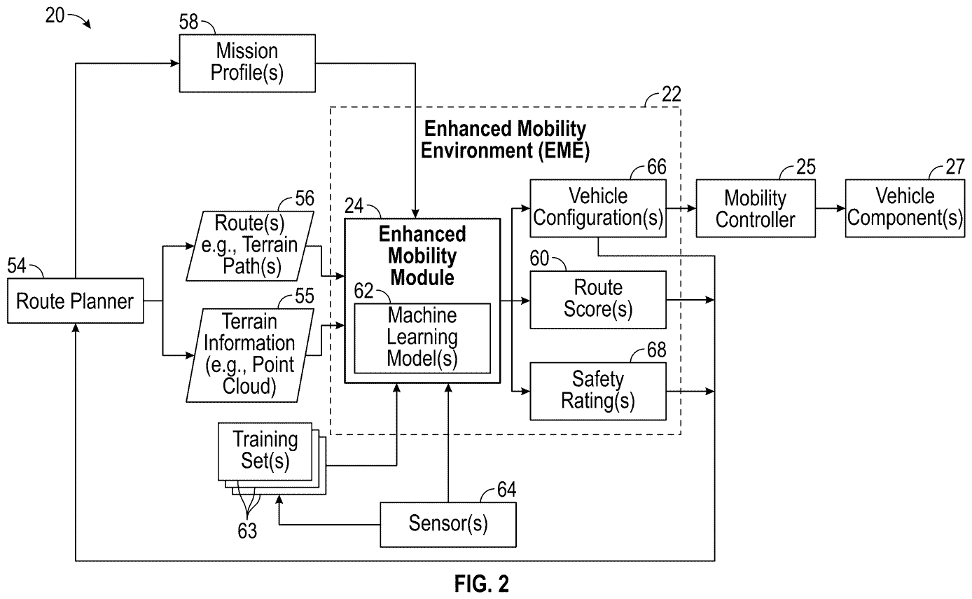

The system 20 may utilize a set of application program interfaces (API) to establish a relationship (e.g., communication) between the EMM 24, the autonomous driving module 51 and/or mobility controller 25. The set of APIs and an orchestrator software module may be utilized to govern the interaction of the route planner 54 with ML model(s) 62 (FIG. 2) and the mobility (e.g., suspension) controller 25.

Referring to FIG. 2, with continuing reference to FIG. 1, the route planner 54 may be operable to generate one or more routes 56 associated with a vehicle which may incorporate any of the functionality disclosed herein such as the mobility controller 25. The EME 22 may be operable to obtain (e.g., from the route planner 45) at least one proposed route 56 for a vehicle and a mission profile 58 associated with the route 56.

The EMM 24 may be adapted for use in robotic or crewed vehicles and may built on algorithms developed over decades of ground vehicle experience. The EMM 24 may include a multibody physics simulation environment, which may be used to create an extensive capability model of scenarios for a given vehicle platform. The EMM 24 may be operable to communicate with a vehicle control system such as the autonomous driving module 51 (e.g., autonomy stack or robotic technology kernel (RTK)). A robot supplier may define an autonomy stack. In implementations, the autonomy stack may assume the suspension is fixed, rather than being adaptive. Utilizing the techniques disclosed herein, one or more suspension settings associated with a present state of the adaptive suspension system may be changed to achieve one or more objectives specified in the mission profile 58 when traversing the selected route 56.

The route planner 54 and/or another portion of the autonomous driving module 51 may be operable to perform route planning functions for the respective vehicle. An iterative loop of communication between the autonomous driving module 51 and the EMM 24 may be used to determine a suitable (e.g., optimum) route 56 for the vehicle based upon overall vehicle capabilities and/or mission profile (e.g., objectives) 58.

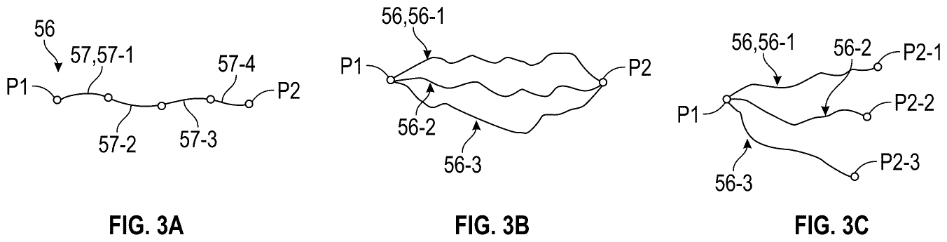

Various mission profiles 58 may be established and communicated to the EMM 24. The mission profile 58 may include one or more parameters including an (e.g., minimum, maximum, average, etc.) traverse speed(s), sensor and/or vehicle platform stability threshold(s), and/or noise (e.g., stealth) limit(s) for one or more segments 57 of the route 56 and/or the overall route 56 (see, e.g., FIG. 3A). The EMM 24 may be operable to set a (e.g., optimal) suspension configuration sufficient to achieve a specified speed (e.g., across an open field), a specified stability (e.g., sensor mast), and/or an acoustic signature for stealth (e.g., relatively slow rate of speed) during operation of the vehicle along the route 56. In implementations, the mission profile 58 may include at least one of a preselected velocity threshold, a preselected noise threshold, and/or a preselected stability threshold.

The EME 22 may be operable to obtain evaluate, using at least one machine learning model 62, one or more proposed route(s) 56 with respect to one or more associated mission profile(s) 58. The EME 22 may be operable to assign, using at least one machine learning model 62, one or more route scores 60 to the proposed route 56 based on the respective mission profile 58. The EMM 24 may be operable to assign or otherwise determine one or more route scores 60 from the terrain information (e.g., route profile(s)) 55, which may be provided by the autonomous driving module 51 to the EMM 24. The EMM 24 may be operable to utilize advanced mobility systems (e.g., variable height, variable damping and/or advanced electric drive) to provide additional degrees of freedom to the vehicle and thus further options for routes across the terrain.

An implementation of an EMM may incorporate and/or interface with a large multidimensional lookup table to compare sensed terrain functions to a capability model of previously simulated events. The EMM may be operable to perform an interpolation function that may identify suitable (e.g., optimal) suspension system setting(s) for the suspension system. The EMM may assign a route score to a respective route by determining where the set of sensed conditions fell within the capability model of simulated events.

In performing a preliminary functional proof of concepts of an EMM, simulated data was successfully ingested into a virtual capability model, which included one event demonstrating that simulation data may be used to create a capability model and that it is transferrable. When the model for an interpolation function and the structure of the multidimensional capability model was investigated, the dataset size required to build the capability model and quickly parse through the data within the capability model to find the correct settings seemed unmanageable. The data problem is further compounded when attempting to perform the task on a small vehicle that has limited power and processing capability.

Machine learning (ML) was investigated to train a machine learning model to perform predictions based on the previously mentioned simulation data. The ML model methodology may have multiple advantages over a multidimensional lookup table approach. First, the full capability model dataset does not need to reside on each instance of the controller on a vehicle. While the volume of data to be generated to train the ML model may be the same or similar, training may be performed offline and may be transferred to the enhanced mobility controller in a substantially smaller model, which can predict with similar levels of accuracy. The second benefit is the tools no longer need to be manually configured to parse through the data in real-time. Machine learning principles excel at evaluating massive datasets and determining the optimum method of performing predictions based on the data. They are also capable of doing so without direct human instruction on the method of determining the optimum method of performing predictions.

In implementations, the EMM 24 may include one or more machine learning (ML) models 62. Various machine learning models may be utilized, such as a neural network. The machine learning model(s) 62 may be trained utilizing any of the techniques disclosed herein. The machine learning model(s) 62 may be trained with one or more supervised and/or unsupervised training data sets 63.

The EME 22 may be operable to obtain sensor information from one or more sensors 64. The machine learning model(s) 62 and/or another portion of the EMM 24 may be operable to communicate with one or more virtual and/or real sensors 64, including any of the sensors disclosed herein. In implementations, the machine learning model(s) 62 may be operable to receive sensor data and other information from the sensor(s) 64. Sensor data and other information may be associated with one or more training data sets 63, which may be utilized to train the machine learning model(s) 62 to perform any of the functionality disclosed herein. The machine learning model(s) 62 may be trained with at least one training set 63 including sensor information generated

by a virtual instance of the one or more sensors 64 during traversal of a virtual instance of the vehicle along one or more virtual routes 56 through a simulated terrain with one or more associated mission profiles 58. The virtual instance of the vehicle may be associated with a virtual instance of one or more sensors 64. The training set(s) 63 may include sensor information generated by the virtual instance of one or more sensors 64. The training set(s) 63 may include sensor information generated by a physical instance of one or more sensors 64 during traversal of a physical instance of the vehicle along one or more physical routes 56 through a physical terrain with one or more associated mission profiles 58.

The machine learning model(s) 62 may incorporate feature importance selection regarding sensor telemetry data, which may reduce processing burden by selectively ignoring incoming telemetry data that may not be useful to the stated goal, which may be defined in the mission profile 58. In scenarios, not all sensors 64 on a vehicle may necessarily be considered informative to the ML model(s) 62 for determining suspension settings and predictive route scoring. Feature selection utilizing feature importance analysis from the modeling process may reduce computational process burden if the ML model 62 learns not all sensor data, which may tend to be extremely large in size for processing and storage, is required for predictive inference by the ML model 62.

To optimize vehicle operational performance to meet and/or exceed requirements, one typically performs iterative modeling and simulation tasks. Model frameworks have been created in MSC Adams™ with Matlab™/Simulink™ performing modeling of the semi-active damping and the RHCS hydraulic systems. These systems allow for complex modeling, including existing mobility algorithms.

The disclosed techniques may include performing one or more simulations to generate outputs including motion and power of all physical vehicle components 27 independently and/or collectively. The simulation outputs may be associated with one or more training data sets 63 for training the ML model(s) 62. The simulation outputs may provide a tremendous source of data with which to train the ML model(s) 62 without the substantial upfront cost of running physical miles with a vehicle test asset. While it may be important to incorporate vehicle data to train the model(s) 62 once there is a large fleet generating data, the cost of obtaining data from actual vehicle operation may be prohibitive in the early phases and may also provide a reduced benefit when the ML model(s) 62 may be relatively untrained.

Vehicle suspension engineering and manufacturers can support multiple levels of vehicle mobility modeling and simulation, using software platforms such as VEHDYN™, Matlab™/Simulink™, MSC Adams™ & Easy5™ to create a dynamic model for individual components, such as the InArm®, Smart Track Tensioning System™, as well as full vehicle multibody dynamic vehicle models to provide feedback on vehicle mobility performance.

The ML model(s) 62 may be trained using (e.g., extensive) simulation and/or real-world data. The ML model(s) 62 may be used in conjunction with one or more control algorithms to adjust and/or otherwise set one or more parameters of an adaptable advanced suspension system, such as the ride height control system 31. The EME 22 may be operable to cause (e.g., prior to traversal of the at least one proposed route 56) at least one adjustment to an adaptive suspension system of the vehicle, which may occur in response to receiving an approval of the proposed route 56 based on the assigned route score(s) 60. The EME 22 may be operable to cause the adjustment(s) prior to traversal of the approved route 56.

Mobility system components may be modeled for use in training the machine learning model(s) 62. System components, including adaptive suspension components and system sensors 64 associated with a vehicle, may be simulated for training the machine learning model(s) 62. In implementations, the machine learning model(s) 62 may be subsequently trained with data generated by real-world vehicle performance.

The route planner 54 may utilize various techniques for communicating the mission profile 58 associated with one or more (e.g., proposed) routes 56 to the EMM 24. The route planner 54 may include a system functional definition to provide mission profile criteria weighting to the EMM 24 of the ideal system performance for a given mission profile 58. The criteria weighting may define a set of system mission (e.g., operational) profiles for which the EMM 24 may optimize using the trained machine learning model(s) 62.

The EMM 24 may include scoring criteria for generating the route scores 60. The machine learning model 62 may be operable to assign route scores 60 based on the scoring criteria. In implementations, the route score 60 may be assigned a value within a preselected range (e.g., 1/easy to 10/hard), a percent chance of achieving the parameter(s) specified in the mission profile 58 (80% likelihood of keeping stability of sensor mast, maintaining a specified speed across the terrain, etc.). The machine learning model 62 may be operable to assign an absolute score 60 and/or relative scores 60 for any and/or all proposed routes 56 that the route planner 54 may determine to be feasible.

The EMM 24 may be operable to receive a single route 56 (e.g., FIG. 3A) and/or a set of proposed routes 56 (e.g., FIGS. 3B-3C) from the route planner 54. The set of routes 56 associated with a common origin, common destination and/or the same mission profile(s) 58. In the implementation of FIG. 3A, the route 56 may include a plurality of segments 57 (indicated at 56-1 to 56-4) established between a first (e.g., starting) point (e.g., origin) P1 and a second (e.g., ending) point (e.g., destination) P2. In the implementation of FIG. 3B, a set of routes 56 (indicated at 56-1 to 56-3) may be established between a common point P1 and a common point P2 but may deviate between the points P1, P2. In the implementation of FIG. 3C, a set of routes 56 (indicated at 57-1 to 57-3) may be associated with a common point P1 but may deviate with respect to points P2 (indicated at P2-1 to P2-3). The EMM 24 may be operable to receive any number of proposed routes 56 in accordance with the teachings disclosed herein. In implementations, the machine learning model 62 may be operable to evaluate sets of proposed routes 56 and associated segments 57 iteratively as a set of branches of a (e.g., decision) tree prior to and/or during traversal of the vehicle across the terrain. More and more options may be provided depending on the route 56 and/or segment 57 selected by the route planner 54. The route planner 54 may propose a subsequent set of proposed routes 56 upon selection of a segment 57, which may originate from a common (e.g., end) point along the segment 57.

The route planner 54 may be operable to select one of the proposed routes 56 based on the assigned route score(s) 60. The machine learning model 62 may be operable to generate recommended values for one or more parameters of a (e.g., current) vehicle configuration 66 to achieve the mission profile 58 for the respective route 56.

The EMM 24 may be operable to save the recommended values of the respective vehicle configuration 66 associated with the route score 60. The EMM 24 may be operable to save the recommended values in memory. The EMM 24 may be operable to retrieve the recommended values and then communicate the values to the mobility controller 25 for varying a condition of the respective vehicle component(s) 27 (e.g., change the suspension settings) in response to approval of the respective route 56 by the route planner 54.

The EME 22 may be operable to communicate the route score(s) 60 to the route planner 54. The route scores 60 may be communicated to the route planner 54 on an iterative basis, which may continuously provide feedback to the route planner 54 on the (e.g., intended or proposed) route path 56 to be taken. In implementations, the EMM 24 may be operable to communicate feedback to the route planner 54, including the route scores 60 and/or other information generated by the machine learning model 62.

The machine learning model 62 may operate based upon a set of inputs and outputs previously defined to optimize overall system performance for given mission (e.g., operational) profile(s) 58 based on a range of available suspension system settings for the respective vehicle, which may be defined in a respective vehicle configuration 66. The EMM 24 may be operable to access a suspension system operational range definition associated with the vehicle. The machine learning model(s) 62 may be trained with suspension system operational range definitions of various vehicles and simulated and/or real routes, which the machine learning model(s) 62 may utilize to adapt to various terrain and operational profiles. The machine learning model(s) 62 may be operable to generate the route score 62 based on the suspension system operational range definitions for the vehicle associated with the route 56.

A design of experiment included a comprehensive list of terrain driving events simulated in MSC Adams™. A comprehensive set of operational event combinations are provided using US Government profile courses, while minimizing the need for custom terrain creation within the simulation environment. A range of suspension system settings may be defined in combination with the provided terrain profiles to provide a statistically significant coverage of all possible events within the design of experiments.

A mobility model within a simulation environment, such as MSC Adams™, may incorporate a suite of virtual sensors. An output file format may be defined to train the machine learning model(s) 62. The inputs for the machine learning model 62 may include terrain profiles, as well as virtual sensor telemetry data. A series of simulations in the simulation environment (e.g., with co-simulation of adaptive suspension components within Matlab™ Simulink™) based upon the terrain events and suspension system settings may be utilized. The simulations may be supplemented with existing simulation data.

The sensor information generated by a virtual instance of one or more sensors 64 associated with the vehicle may be provided in the training data set(s) 63 for training the machine learning model 62. The virtual and real (e.g., live) sensor information may be stored in the training data set(s) 63 in a common format such that the virtual and real sensor information may be indistinguishable by the machine learning model 62.

Data transformation on the terrain profiles may be performed to simulate point cloud data, which may be similar to point cloud data generated by light detection and ranging (LIDAR) systems taken from the continuous terrain profiles.

Model development and training may be performed based on the simulation data and model validation to measure performance of the machine learning model(s) 62 (e.g., where model predictions are effective at predicting vehicle configurations given terrain data and sensor telemetry data), and evaluate the model 62 efficacy (e.g., the model's ability to learn from input data).

Various techniques may be utilized to validate the ML model(s) 62 trained with simulation data. The ML model 62, once trained, may be shown a new terrain profile, which has previously been unseen. The performance of the ML model 62 may be analyzed in several ways to determine if the model 62 is predicting outcomes that may be consistent with expert predictions. First, the predicted suspension settings may be compared to those that would have been identified by a reactive suspension control algorithm. Second, the predicted route segment scoring generated by the ML model 62 may be compared against performance data from simulation models run within a simulation environment, such as MSC Adams™.

A test plan for real world testing and data collection may be designed to validate the simulation based model development by providing an overlap of a certain set of simulated data with the real-world testing. The test plan may be designed to gather data sufficient to perform model validation and ensure the trained ML model 62 may be equally applicable to real world developed data as it is to simulated data. A vehicle may be outfitted with sensor(s) 64 to obtain sensor data. Real world testing may be performed in accordance with a test plan and may record all data generated by system sensors 64, including terrain sensors.

Integration may be performed of the developed data into the ML model 62. Further validation of the model 62 may be performed with the overlapping data to determine if the model 62 reports similar results with simulated data verses real world data in similar circumstances. The ML model 62 may then be validated with real world generated data.

The ML model(s) 62 may be operable to predict or otherwise generate (e.g., optimal) adaptable suspension settings prior to the vehicle wheels/track physically encountering terrain along the route 56, which may be referred to as “look ahead” adaptive suspensions. Look ahead adaptive suspensions have been developed for commercial automotive systems but have yet to be implemented on military vehicles. In order to demonstrate the efficacy of a look ahead system in providing improved platform performance, simulation models may be performed within a simulation environment such as MSC Adams™ based on reactive algorithms. The suspension settings determined by existing models may be recorded. A second simulation model may be run with the previously recorded suspension settings fed back into the simulation slightly earlier than a reactive model would have been able to determine them. The results may then be compared to the reactive algorithm model. This method may be utilized to determine the efficacy of the ML model(s) 62 in establishing look-ahead predictive suspension functionality.

The ML model(s) 62 and/or another portion of the EMM 24 may be operable to receive terrain information (e.g., profile(s)) 55, such as a point cloud which may be generated by sensor information from the LIDAR unit 53, and/or one or more routes (e.g., terrain paths) 56. The point cloud may be utilized to establish the terrain profile. The route 56 may be a discreet path mapped through the point cloud. The terrain profile may be established utilizing other sensor information, such as by one or more optical sensors. The route 56 may be established with respect to a vehicle midpoint (e.g., between two tracks 41). The EMM 24 may be operable to perform various data reduction functions. The EMM 24 may be operable to reduce the received terrain information 55 by stripping the point cloud data to a certain width relative to a geometry of the vehicle (e.g., a maximum range) and may discard the remaining terrain information 55 from consideration. The EMM 24 may be operable to translate the input data into a data table which may be ingested by the ML model 62. Vehicle geometries may be utilized to calculate time dependent wheel travel for each wheel/roadwheel station based on the point cloud and the (e.g., centerline) route. The centerline route may be defined with respect to a set of proposed routes 56 communicated from the route planner 54 to the EMM 24.

The trained machine learning model(s) 62 may be operable to determine how the vehicle will react as it traverses the route 56, which may correspond to a height map. The ML model 62 may be operable to predict in (e.g., real time) how the vehicle will perform. The ML model 62 may be operable to optimize any set of parameters of a vehicle configuration 66 associated with the vehicle based on the mission profile 58 (e.g., speed, stealth, sensor stability, etc.). The mission profile 58 may be presented to the machine learning model 62 with the proposed route 56.

The vehicle configuration 66 may include one or more parameters associated with various vehicle components 27, including suspension settings, travel, etc. The vehicle components 27 may include any of the components disclosed herein.

The EMM 24 may be operable to determine the terrain height at a specified distance from the nominal centerline based on vehicle track width. The EMM 24 may be operable to calculate the terrain height for each wheel station on each side of the vehicle. The EMM 24 may be operable to generate output, such as a data table with time on one axis and a value of height for each wheel station on the other axis. In implementations, the EMM 24 may be operable to determine height maps (e.g., profile of the terrain) for left and right tracks 41 of the vehicle based on the virtual and/or real terrain information 55. The ML model 62 may be operable to receive the height map(s) in relation to the wheel or track height(s).

The route planner 54 and/or EMM 24 may be operable to divide a continuous route 56 into a set of route segments 57 (e.g., FIG. 3A) based on an appropriate granularity level. It should be understood that the route 56 may be divided into any number of segments 57 in accordance with the teachings disclosed herein.

The set of route segments 57 may be utilized to create a series of discreet scenarios. The set of route segments 57 may be utilized such that feedback from the EMM 24 to the route planner 54, including route scores 60, may be performed segment 57 by segment 57. In a scenario, if the route planner 54 provides 200 ft of route length for a route 56, and 190 feet are smooth road but there is a 50 ft deep hole in the middle, the EMM 24 may assign 95% of the route segment(s) 57 as having a high route score 60 and only the one segment 57 as having a relatively low route score 60.

The ML model(s) 62 may be operable to assign route scores 60 based on various criteria, which may be specified in a mission profile 58 associated with the respective route 56 and/or route segments 57. In implementations, the ML model(s) 62 may be operable to assign route score(s) 60 to the respective segments 57 of the route 56 based on a speed parameter specified in the mission profile 58. The route planner 54 may be operable to determine the most appropriate speed based on mission objectives, which may be specified in the mission profile 58.

The ML model(s) 62 may be operable to recommend varying or otherwise setting one or more suspension settings to achieve an (e.g., optimal) execution of the route 56. The ML model 62 may be operable to recommend a set of suspension settings to achieve one or more parameters specified in the mission profile 58. The EMM 24 may be operable to communicate the recommended suspension settings of the vehicle configuration 66 to the mobility controller 25 in response to approval of the route 56. The mobility controller 25 may be operable to vary the adaptive suspension according to the recommended suspension settings. In scenarios, the recommended suspension settings may reduce a likelihood of the vehicle bottoming out along the route 56 by increasing the ride height (e.g., by three inches) while maintaining a sufficient speed to meet a minimum speed threshold specified in the mission profile 58. In scenarios, the mission profile 58 may include moving between point P1 and point P2 within a specified time limit (e.g., FIGS. 3A-3C). The ML model(s) 62 may be operable to recommend varying or otherwise setting one or more suspension settings that may be sufficient to reach point P2 within the specified time limit. The ML model 62 may be trained to maximum (or minimize) speed to achieve the associated parameters of the mission profile 58. The route planner 54 may be operable to decide whether to approve the route 56 and/or recommended changes to the vehicle configuration 66, including the suspension settings.

The ML model(s) 62 may be operable to provide a set of route scores 60 for respective segments 57 of the route 56, which may be broken up by scoring type. In implementations, the ML model(s) 62 may be operable to assign each of these score types over a series of speeds (e.g., above a preselected speed threshold). The route planner 54 may be operable to select one of the routes 56 based on the assigned route scores 60 and mission profile 58.

The machine learning model(s) 62 may be operable to assign one or more (e.g., expected) safety ratings 68 to the respective routes 56 and/or route segments 57. The machine learning model(s) 62 may be operable to assign safety rating(s) 68 to the proposed route(s) 56 based on a vehicle configuration 66 and the associated mission profile 58. The safety rating 68 may indicate the probability of an adverse event (e.g., on side slope and execution of the route 56 may require a rapid turn at speed, which may result in tip over of the vehicle). The machine learning model 62 may be operable to determine the route score 60 based on the assigned safety rating(s) 68. In scenarios, the route score 60 may be optimized for speed to achieve the mission profile 58. The machine learning model(s) 62 may assign a relatively low safety rating 68 (e.g., 4 out of 10) for the route 56 due to relatively harsh terrain.

Various techniques may be utilized to determine the safety rating 68. The machine learning model(s) 62 may be operable to determine the safety rating 68 based on various parameters, including characteristics of the route 56 (e.g., topography, soil conditions, obstacles, vegetation, etc.), present speed and/or speed specified in the mission profile 56, vehicle configuration 66 and associated present suspension settings and vehicle dynamics, etc. The machine learning model 62 may be trained with one or more training data sets 63 associated with any of the information disclosed herein to determine the safety ratings 68. The machine learning model 62 may be trained with simulated and/or real data to determine the safety ratings 68.

The EMM 24 may be operable to communicate the safety rating(s) 68 and route score(s) 60 and/or recommended set of parameters for the vehicle configuration 66 to the route planner 54. The recommended set of parameters may reduce a likelihood of occurrence of an adverse event associated with the safety rating 68. In implementations, the ML model 62 may be operable to determine a set of route scores 60 for a single route 56. The ML model 62 may be operable to determine a route score 60 based on the current vehicle configuration 66, including suspension settings, and may be operable to determine another route score 60 based on the recommended changes to parameter(s) of the current vehicle configuration 66, including the suspension settings. The route score 60 based on the current suspension settings may be useful for an adaptive suspension assembly and/or fixed suspension assembly (e.g., to avoid roll over).

The route planner 54 may be operable to approve the recommended set of parameters. The EMM 24 may be operable to generate a safety indicator (e.g., warning) associated with the safety rating 68. A user may interact with the route planner 54 to override the safety indicator and approve the route 56 without adjustment of the state of the vehicle component(s) 27 according to the recommended set of parameters.

The EMM 24 may be operable to communicate the route score(s) 60, including respective segments 57 of the route 56, to the route planner 54. The EMM 24 may be operable to communicate the route score(s) 60 in a format the route planner 54 can ingest. The route planner 54 may be operable to ingest a single route 56 and/or a set of segments 57 at a time. The EMC 21 may be operable to execute the ML model(s) 62.

The EMM 24 may be operable to establish a feedback (e.g., iterative) loop with the route planner 54. An iterative loop may be established where the route planner 54 may provide the proposed route(s) 56, mission profile(s) 58 and/or other information to the ML model(s) 62 and/or another portion of the EMM 24, which may calculate route scores 60 for the respective segments 57 of the route 56, which may then be fed back to the route planner 54. The route planner 54 may be operable to decide if a route 56 may be acceptable or to propose another route 56 based on the route score(s) 60, safety rating(s) 68, etc. If the route planner 54 decides to propose an alternate route 56, the route planner 54 can then communicate a new set of data to the EMM 24 for generating respective route score(s) 60.

The diagnostics and prognostics module (DPM) 23 (FIG. 1) may be operable to perform various diagnostics and prognostics functionality. The DPM 23 may be operable to determine and/or predict the health of one or more vehicle components 27, including any of the components disclosed herein. The determined and/or predicted health may include a wear (e.g., failure) state of the respective component 27. The DPM 23 may be operable to perform various diagnostic functions by comparing various vehicle sensor data and/or other information to determine problems such as a broken track, broken wheels, etc. associated with the vehicle.

The DPM 23 may be operable to provide maintenance recommendations based on sensor data. If the track tensioner 43 has been extending over a predefined time period, the DPM 23 may be operable to provide an indication of when to maintain a uniform track tension. The DPM 23 may be operable to identify a likely track change (e.g., for a band track) at a predetermined date or time based on sensor-determined wear and/or stretch. The DPM 23 may be operable to identify suspension seal wear through sensing oil inputs while maintaining the height of the RHCS 31.

The DPM 23 may be operable to perform fault detection using sensor readings and/or comparisons. The DPM 23 may be operable to determine a thrown track by causing a full extension of the track tensioner based on the sensed condition(s).

The DPM 23 may be operable to diagnose a problem based on data from one or more sensors 64, including any of the sensors disclosed herein. The DPM 23 may be operable to determine a blown track in response to a sensed condition of the track tensioner 43 at full extension. The DPM 23 may be operable to determine a catastrophic oil leak by sensing the extension of the track tensioner 43 with a pressure transducer.

The DPM 23 may be operable compare the extension measurement to the vehicle motion and sprocket 49 motion to determine the track condition with relatively more certainty. In scenarios, the track tensioner 43 may indicate full extension, but the sprocket 49 and vehicle (without spinning in circles) may be moving at a 5 mph equivalent, which may indicate a blown seal in the tensioner 43 or a faulty transducer.

The EMM 24 may be operable to obtain the determined and/or predicted health of one or more vehicle components 27, including any vehicle components associated with execution of the route 56. In implementations, the machine learning model 62 may be operable to determine a health of one or more vehicle components 27. The machine learning model 62 may be operable to determine the route score(s) 60 based on the determined health. The machine learning model 62 may be operable to generate the route score(s) 60 and/or safety rating(s) 68 based on an indication that one or more vehicle components 27 are functioning in a degraded state. The machine learning model 62 may be operable to generate the route score 60 and/or safety rating 68 based on the determined and/or predicted health. The ML model 62 may be operable to change (e.g., reduce) the route score 60 based on a predicted and/or determined wear (e.g., failure) condition of the vehicle component(s) 27, such as a condition associated with a thrown track or failed shock absorber. In implementations, the machine learning model 62 may be operable to reduce a route score (e.g., from a score of 9 based on speed only to an adjusted score of 6 to account for the determined and/or predicted health) due to an imminent failure of a suspension component 37 if the vehicle traverses the respective route 56. The machine learning model 62 may be operable to cause one or more adjustments to the adaptive suspension system based on the determined health.

Trained machine learning models 62 may be released in global and local variations. The global releases may be initially trained from simulation and then may be released to a real-world testing fleet. The vehicle fleet may be capable of localized on-vehicle training. Each test/training vehicle may then generate a modified local model 62 based on its own experience and operational environment. Based on experiences, each local model 62 may be trained with respect to the terrain and conditions encountered by that vehicle. The local models 62 may be utilized to train the next global model 62, which may be released as the next major release to the entire fleet. The global model 62 may encompass changes developed in the local model(s) 62 at each subsequent release. This process can continue indefinitely to continuously update the models 62 based on the most recent experience.

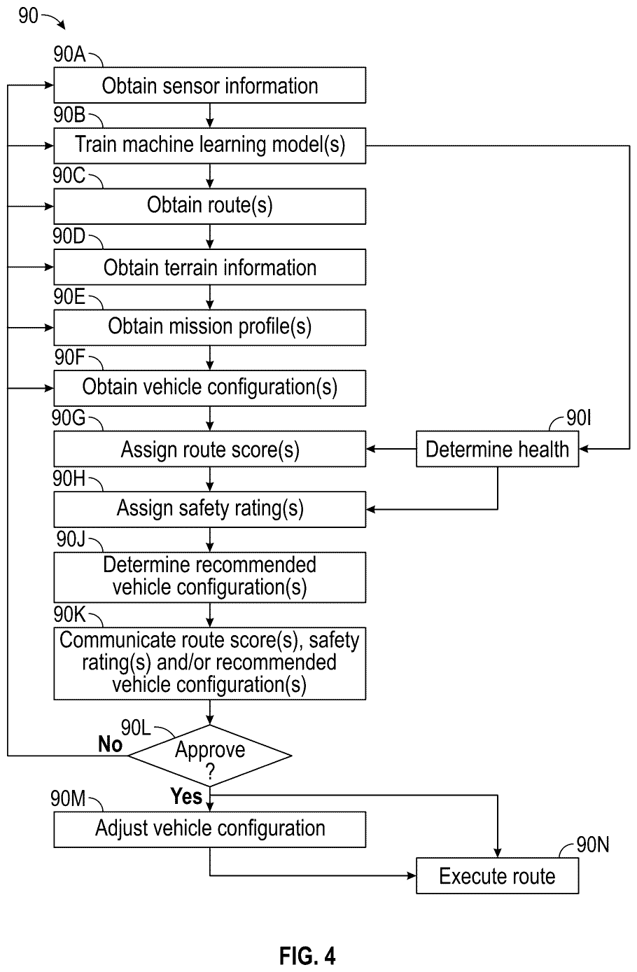

FIG. 4 discloses a method 90 in a flowchart for vehicle route planning and execution according to an implementation. The vehicle may include any of those disclosed herein. The EMC 21 and/or associated modules may be operable to execute any of the functionality of the method 90 and/or techniques disclosed herein. Reference is made to the system 20 of FIGS. 1-2.

At block 90A, sensor information may be obtained. The sensor information may be obtained from any of the sensors disclosed herein, including virtual and/or physical instances of the sensor(s) 64. The sensor information may be captured during simulated and/or real operation of the vehicle. A virtual instance of the vehicle may be associated with a virtual instance of one or more sensors 64. A physical instance of the vehicle may be associated with a physical instance of one or more sensors 64, which may correspond to respective virtual instances of the sensors 64. Block 90A may include obtaining virtual sensor information from one or more virtual sensors 64. The virtual sensor(s) 64 may be operable to measure a condition of a virtual instance of one or more respective vehicle components 27 and/or operating environment of the vehicle along one or more routes 56. The vehicle components 27 may include any of the components disclosed herein. Block 90A may include obtaining real sensor information measured by one or more physical sensors 64 during vehicle operation. The physical sensor(s) 64 may be associated with the respective virtual sensor(s).

The vehicle component(s) 27 may include one or more suspension components (e.g., hardware) 37. In implementations, the vehicle may be a tracked vehicle. The suspension component(s) 37 may include road wheel(s) 39 and/or a track 41 mounted on the road wheel(s) 39.

At block 90B, one or more machine learning models 62 may be trained. The machine learning model(s) 62 may be trained utilizing any of the techniques disclosed herein, including supervised and/or unsupervised techniques. The machine learning model 62 may be trained with any of the training data and/or other information disclosed herein, including virtual and/or real sensor information, which may be presented to the machine learning model 62 in one or more training data sets 63. The training set(s) 63 may include sensor information generated by the virtual instance of one or more sensors 64. In implementations, the machine learning model 62 may be trained with one or more training sets 63 including data generated during traversal of a virtual instance of the vehicle along one or more virtual routes 56 through a simulated terrain with one or more associated mission profiles 58. The training set(s) 63 may include sensor information generated by a physical instance of the one or more sensors 64 during traversal of a physical instance of the vehicle along one or more physical routes 56 through a physical terrain with one or more associated mission profiles 58.

The machine learning model(s) 62 may be trained for only one vehicle or vehicle type, or may be trained for a fleet of vehicles, which may include respective suspension configurations. The machine learning model(s) 62 may be trained for one or more mission profiles 58, routes 56, terrain information 55 and/or operating environments of the respective vehicle(s). In implementations, the machine learning model 62 may be trained for only one vehicle associated with a respective suspension configuration. The suspension configuration may be adaptive. The machine learning model 62 may be trained with virtual and/or real sensor information associated with different suspension configurations for the same and/or different vehicles and/or vehicle types.

At block 90C, one or more (e.g., proposed or selected) routes 56 may be obtained. The routes 56 may be obtained utilizing any of the techniques disclosed herein. In implementations, block 90C may include obtaining, from the route planner 54, at least one or more proposed routes 56 for the vehicle(s).

At block 90D, terrain information 55 may be obtained, including any of the terrain information (e.g., profile(s)) disclosed herein. The terrain information 55 may be obtained utilizing any of the techniques disclosed herein.

At block 90E, one or more mission profiles 58 may be obtained. In implementations, block 90E may include obtaining, from the route planner 54, one or more mission profiles 58 associated with the proposed route(s) 56. The mission profiles 58 and/or associated parameters may be obtained utilizing any of the techniques disclosed herein.

At block 90F, one or more vehicle configurations 66 and/or associated parameters for the respective vehicle(s) and/or vehicle components 27 may be obtained. The vehicle configuration(s) 66 and/or associated parameters may be obtained utilizing any of the techniques disclosed herein.

At block 90G, one or more route scores 60 may be determined and/or assigned to the proposed route(s) 56. The route scores 60 may be determined utilizing any of the techniques disclosed herein. In implementations, block 90G may include assigning, using at least one machine learning model 62, route score(s) 60 to the proposed route(s) 56 based on the respective mission profile(s) 58.

At block 90H, one or more safety ratings 68 may be determined and/or assigned to the route score(s) 60 and/or proposed route(s) 56. The safety ratings 68 may be determined utilizing any of the techniques disclosed herein.

At block 90I, the health of the vehicle and/or vehicle component(s) 27 may be determined, including any of the components disclosed herein such as one or more suspension components of the vehicle. The health may be determined utilizing any of the techniques disclosed herein, including by the diagnostics and prognostics module 23. In implementations, block 90I may include determining, using the at least one machine learning model 62, a health of one or more vehicle (e.g., suspension) components 27 of the vehicle. The determined health may include diagnostics and/or prognostics for the respective vehicle component(s) 27.

At block 90J, one or more (e.g., recommended) vehicle configurations 66, or parameters thereof, may be determined utilizing any of the techniques disclosed herein.

At block 90K, the route score(s) 60, safety rating(s) 68 and/or recommended vehicle configuration(s) 66 may be communicated to the route planner 54 and/or another portion of the system 20.

At block 90L, the route 56 and/or associated route score(s) 60, safety rating(s) 68 and/or recommended vehicle configurations 66 may be approved or rejected. One or more iterations of any of the blocks 90A-90L may be performed, including in response to the route 56 and/or associated route score(s) 60, safety rating(s) 68 and/or recommended vehicle configurations 66 being rejected. Block 90L may include receiving the approval.

At block 90M, one or more vehicle components 27 and/or subsystems of the vehicle may be adjusted, which may occur in response to the approval of a route 56 at block 90L. Block 90M may include causing, performing, and/or communicating one or more adjustments to the vehicle configuration 66 and/or associated components 27 in response to the approval at block 90L. In implementations, the mobility controller 25 may selectively adjust a condition of the vehicle and/or vehicle component(s) 27 based on the recommended and/or approved parameter(s). In implementations, block 90M may include causing, prior to traversal of the (e.g., approved) route 56, at least one adjustment to an adaptive suspension system of the vehicle in response to receiving an approval of the route 56 based on the assigned route score(s) 60, safety rating(s) 68 and/or recommended vehicle configuration 66 and/or parameter(s) thereof.

At block 90N, the approved route 56 may be executed. Block 90N may include executing the route 56 subsequent to adjusting the vehicle configuration 66 and/or a state of the associated vehicle component(s) 27 at block 90M.

The foregoing description, for purpose of explanation, has been described with reference to specific arrangements and configurations. However, the illustrative examples provided herein are not intended to be exhaustive or to limit embodiments of the disclosed subject matter to the precise forms disclosed. Many modifications and variations are possible in view of the disclosure provided herein. The embodiments and arrangements were chosen and described in order to explain the principles of embodiments of the disclosed subject matter and their practical applications. Various modifications may be used without departing from the scope or content of the disclosure and claims presented herein.

Although the different examples have the specific components shown in the illustrations, embodiments of this disclosure are not limited to those particular combinations. It is possible to use some of the components or features from one of the examples in combination with features or components from another one of the examples.

Although particular step sequences are shown, described, and claimed, it should be understood that steps may be performed in any order, separated or combined unless otherwise indicated and will still benefit from the present disclosure.

What is claimed is:

1. A mobility system for a vehicle comprising:
a computing device including one or more processors coupled to memory, the one or more processors collectively operable to execute a mobility environment, and the mobility environment operable to:
obtain, from a route planner, a proposed route for a vehicle and a mission profile associated with the proposed route;
assign, using a machine learning model, a route score to the proposed route based on the respective mission profile, the machine learning model trained with a training set; and
communicate the route score to the route planner.

2. The system as recited in claim 1, wherein:
the training set includes information associated with traversal of a virtual instance of the vehicle along one or more virtual routes through a simulated terrain with one or more associated mission profiles.

3. The system as recited in claim 2, wherein the virtual instance of the vehicle is associated with a virtual instance of one or more sensors, and the training set includes sensor information generated by the virtual instance of one or more sensors.

4. The system as recited in claim 1, wherein:
the training set includes sensor information generated by a physical instance of one or more sensors during traversal of a physical instance of the vehicle along one or more physical routes through a physical terrain with one or more associated mission profiles.

5. The system as recited in claim 1, wherein the mobility environment is operable to cause an adjustment to an adaptive suspension system of the vehicle in response to receiving an approval of the proposed route based on the assigned route score.

6. The system as recited in claim 5, wherein the mobility environment is operable to cause the adjustment prior to traversal of the approved route.

7. The system as recited in claim 1, wherein the mission profile includes at least one of a preselected velocity threshold, a preselected noise threshold, and a preselected stability threshold.

8. The system as recited in claim 1, wherein the proposed route includes a set of different routes associated with a common origin and/or the same mission profile.

9. The system as recited in claim 1, wherein the machine learning model is operable to assign a safety rating to the proposed route based on a vehicle configuration and the associated mission profile.

10. The system as recited in claim 9, wherein the machine learning model is operable to determine the route score based on the assigned safety rating.

11. The system as recited in claim 1, wherein the machine learning model is operable to:
determine a health of one or more vehicle components; and
determine the route score based on the determined health.

12. A mobility system for a vehicle comprising:
a computing device including one or more processors coupled to memory, the one or more processors collectively operable to execute a mobility environment, and the mobility environment operable to:
obtain sensor information from one or more sensors;
obtain a proposed route for a vehicle and a mission profile associated with the proposed route;
evaluate, using a machine learning model, the proposed route with respect to a mission profile, the machine learning model trained with a training set; and
cause, prior to traversal of the proposed route, an adjustment to an adaptive suspension system of the vehicle.

13. The system as recited in claim 12, wherein:
the training set includes sensor information generated by a virtual instance of the one or more sensors during traversal of a virtual instance of the vehicle along one or more virtual routes through a simulated terrain with one or more associated mission profiles; and/or
the training set includes sensor information generated by a physical instance of the one or more sensors during traversal of a physical instance of the vehicle along one or more physical routes through a physical terrain with one or more associated mission profiles.

14. The system as recited in claim 12, wherein the machine learning model is operable to:
determine a health of one or more vehicle components; and
cause the adjustment to the adaptive suspension system based on the determined health.

15. The system as recited in claim 12, wherein the mobility environment is operable to:
assign, using the machine learning model, a route score to the proposed route based on the respective mission profile; and
communicate the route score to a route planner for approval of the proposed route.

16. A method for route planning of a vehicle comprising:
obtaining, from a route planner, a proposed route for a vehicle and a mission profile associated with the proposed route;
assigning, using a machine learning model, a route score to the proposed route based on the respective mission profile, the machine learning model trained with a training set; and
communicating the route score to the route planner.

17. The method as recited in claim 16, wherein:
the training set includes information associated with traversal of a virtual instance of the vehicle along one or more virtual routes through a simulated terrain with one or more associated mission profiles;
the virtual instance of the vehicle is associated with a virtual instance of one or more sensors, and the training set includes sensor information generated by the virtual instance of one or more sensors; and/or
the training set includes sensor information generated by a physical instance of the one or more sensors during traversal of a physical instance of the vehicle along one or more physical routes through a physical terrain with one or more associated mission profiles.

18. The method as recited in claim 16, further comprising:
causing, prior to traversal of the proposed route, an adjustment to an adaptive suspension system of the vehicle in response to receiving an approval of the proposed route based on the assigned route score.

19. The method as recited in claim 18, further comprising:
determining, using the machine learning model, a health of one or more suspension components of the vehicle; and
causing the adjustment to the adaptive suspension system based on the determined health.

20. The method as recited in claim 19, wherein the vehicle is a tracked vehicle, and the one or more suspension components include a road wheel and/or a track mounted on the road wheel.
